(19) United States
(12) Patent Application Publication
(10) Pub. No.: US 2013/0008491 A1
(43) Pub. Date: Jan. 10, 2013

(54) PLASTICS PHOTOVOLTAIC MODULE AND PROCESS FOR ITS PRODUCTION

(75) Inventors: Thomas Rhein, Stadecken-Elsheim (DE); Torsten Frank, Gernsheim (DE); Gunther Benz, Griesheim (DE); Uwe Numrich, Gross-Zimmern (DE); Florian Schwager, Muenster (DE); Michael Olbrich, Karlstein (DE)

(73) Assignee: Evonik Industries AG, Essen (DE)

(21) Appl. No.: 13/636,535

(22) PCT Filed: May 30, 2011
(86) PCT No.: PCT/EP2011/058783

§ 371 Date: Sep. 21, 2012

(30) Foreign Application Priority Data
Jun. 15, 2010 (DE) 10 2010 030 074.8

(51) Int. Cl. H01L 31/048; H01L 31/18

(52) U.S. Cl. 136/251; 438/64; 257/E31.117

(57) ABSTRACT

The invention describes a composite in which solar cells can be encapsulated, being a photovoltaic module, composed of the following elements: an outer layer made of a transparent thermoplastic and/or a barrier foil, and an elastic layer into which the solar cells have been embedded and a barrier foil or a barrier sheet.

### FIELD OF THE INVENTION

The invention relates to a lightweight photovoltaic module (PV) which is highly efficient and which is suitable for use by way of example in the roof region of automobiles or in caravans, and also to a process for its production.

A photovoltaic module hereinafter means an arrangement made of one or more solar cells and of an encapsulation system for the solar cells, and optionally means the means of securing the photovoltaic module on a support.

### PRIOR ART

Photovoltaic modules are of great interest for obtaining energy from sunlight, inter alia in automobiles. Vehicle-integrated power generation is increasingly important in the field of electromobility, as well as for providing energy for “convenience functions”, for example maintaining the charge level of the battery, ventilation of the interior of a parked vehicle, drying of the air ducts and of the air-conditioning heat exchanger in a parked vehicle, and also overall reduction of running time of the air-conditioning system after start. Photovoltaic generators can provide a significant contribution to the energy required by electric drives, by feeding the resultant solar energy into the on-board network or storing it in the vehicle's battery. The solar energy can moreover be used to operate devices that consume electrical power, e.g. refrigerators in caravans, lorries, etc.

Because the surfaces available on automobiles are restricted, there is a particular desire for PV modules with maximum efficiency, attained by way of example by using crystalline PV cells. Weight-saving design is moreover desirable, in particular for use in vehicles of lightweight construction.

The only crystalline photovoltaic roofs currently marketed for automobiles have glass as outer panel (Webasto Solar). The density of glass is about 2.1 times as high as that of an outer panel made of plastic, e.g. polymethyl (meth)acrylate, PMMA.

However, the coefficient of thermal expansion of PMMA, for example, is markedly higher than that of glass.

If, therefore, the glass panel were simply replaced by a plastics panel in a module structure corresponding to the prior art (ESG panel/EVA (ethylene-vinyl acetate copolymer)/PV cells/EVA/barrier foil), the resultant thermal stresses in the crystalline PV cells would therefore be so great, not only during the process of combining the components (sealing/compression at high temperatures around 150 degrees Celsius) but also during subsequent use, as to cause the cells to break apart and become useless.

A general disadvantage of the use of prefabricated glass panels in photovoltaic modules, as is necessary by way of example in the case of single-pane safety glass, is that the process of combining the components of the module cannot take place continuously and is more expensive than continuous processes.

DE 39 24 393 (Röhm GmbH) describes a durably elastic, pressure-sensitive adhesive which comprises no plasticizer. The adhesive is composed of an uncrosslinked copolymer of a monoethylenically unsaturated monomer which contains an amino group and which can be polymerized by a free-radical route and of an alkyl (meth)acrylate.

DE 196 53 605 (Röhm GmbH) describes an adhesive which is composed of from 55% to 99.9% by weight of a (meth)acrylate copolymer of structural and functional (meth)acrylate monomers, where the functional monomers have tertiary or quaternary amino groups, and also of from 0.1% by weight to 45% by weight of a (meth)acrylate polymer or, respectively, (meth)acrylate copolymer containing acid groups; it also comprises a plasticizer.

DE 196 53 606 (Röhm GmbH) describes an adhesive which is composed of from 55% by weight to 99.9% by weight of a (meth)acrylate copolymer of structural and functional (meth)acrylate monomers, where the functional monomers have tertiary or quaternary amino groups, and also of from 0.1% to 15% by weight of an organic di- or tricarboxylic acid; it also comprises a plasticizer.

### Object

Objects according to the invention are therefore:
The development of a PV module with weight considerably reduced in comparison with the prior art.
The development of a plastics PV module with a structure which decouples the thermal expansion of the plastics outer panel from that of the crystalline PV cells, so that no breakage of the cells can occur during thermal stress cycles in service.
The development of a PV module with spherical shape which has been appropriately adapted to the shape of the support used, for example to an automobile roof.
The development of a flexible PV module which can be converted to a spherical shape by low-temperature introduction of curvature, without any resultant damage to, or breakage of, the PV cells.
The development of a production process for the PV module which, when the components are combined, does not produce thermal expansion phenomena that cause breakage of the PV cells.
The development of a low-cost production process which is suitable for continuous production of the PV module.
The development of a shaping process for the PV module which replicates a spherical shape.
The development of an adhesive formulation which ensures adequate weathering resistance over a long period, for example over at most 30 years.
The development of an adhesive formulation which ensures adequate elasticity over a long period.
The protective covering must moreover be inert with respect to the usual effects of the environment, for example rain or hail.
The development of a barrier foil which ensures adequate weathering resistance over a long period.

### Achievement of Object

The objects according to the invention are achieved as follows:

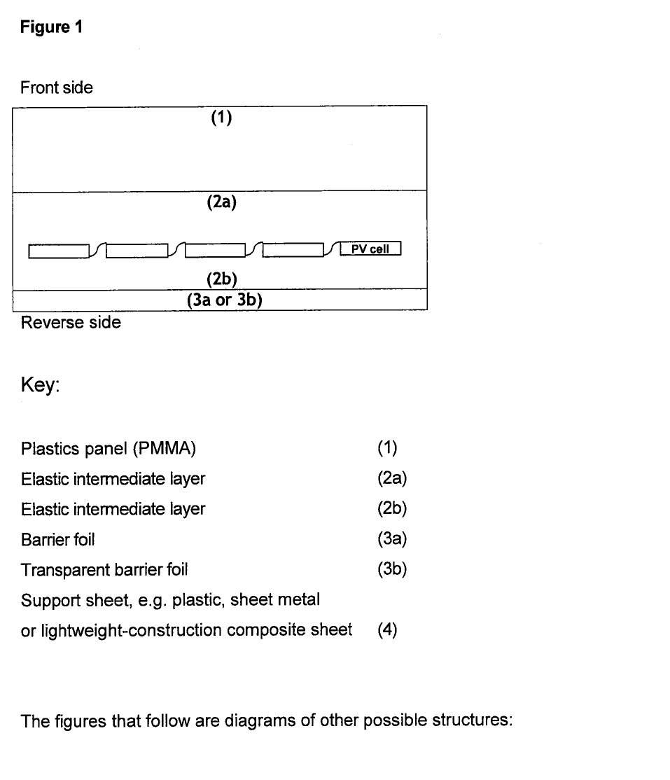

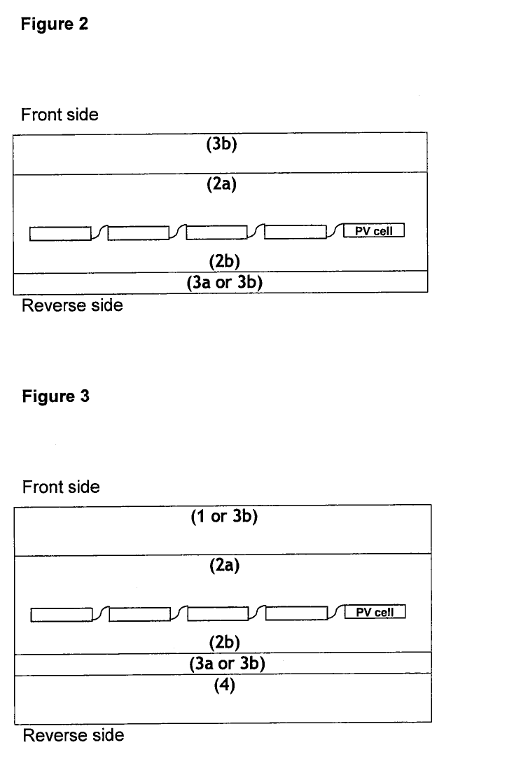

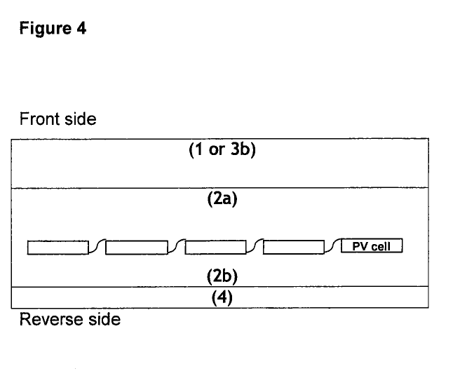

FIG. 1 is a diagram of the structure that achieves the object according to the invention. It is composed of a plastics panel, of an elastic intermediate layer with embedded PV cells and of a barrier foil or of a second plastics panel as barrier sheet.

The structure is composed of a weathering-resistant, transparent plastics panel made of a thermoplastic with adequate mechanical strength, e.g. PMMA (polymethyl methacrylate) or PC (polycarbonate) of thickness about 5 mm. The thickness of the transparent plastics panel made of a thermoplastic is from 1 mm to 10 mm, preferably from 2 mm to 8 mm and very particularly preferably from 3 mm to 6 mm, of an intermediate layer (e.g. a polyacrylate or a silicone of thickness about 0.1 mm-5.0 mm, preferably from 0.15 mm to 4.5 mm and very particularly preferably from 0.2 mm to 4.0 mm thickness) which is durably elastic within the service temperature range (from −40 to +80 degrees C.), in which the PV cells have been embedded, and of a barrier layer or barrier sheet, which protects the PV cells from exterior mechanical and climatic effects (e.g. PET, PVF, PMMA, PC of thickness about 0.1 mm to 4.0 mm).

Polycarbonates are known to persons skilled in the art. Polycarbonates can be regarded formally as polyesters made of carbonic acid and of aliphatic or aromatic dihydroxy compounds. They are readily obtainable by reaction of diglycols or bisphenols with phosgene and, respectively, carbonic diesters in polycondensation and, respectively, transesterification reactions.

Preference is given here to polycarbonates which derive from bisphenols. Particular bisphenols among these are 2,2-bis(4-hydroxyphenyl)propane (bisphenol A), 2,2-bis-(4-hydroxyphenyl)butane (bisphenol B), 1,1-bis(4-hydroxyphenyl)cyclohexane (bisphenol C), 2,2′-methylenediphenol (bisphenol F), 2,2-bis(3,5-dibromo-4-hydroxyphenyl)propane (tetrabromobisphenol A) and 2,2-bis(3,5-dimethyl-4-hydroxyphenyl)propane (tetramethylbisphenol A).

These aromatic polycarbonates are usually prepared by interfacial polycondensation or by transesterification, details being given in Encycl. Polym. Sci. Engng. 11, 648-718.

In interfacial polycondensation, the bisphenols in the form of aqueous alkaline solution are emulsified in inert organic solvents, such as methylene chloride, chlorobenzene or tetrahydrofuran, and reacted with phosgene in a reaction involving stages. Amines are used as catalysts, and phase-transfer catalysts are used in the case of sterically hindered bisphenols. The resultant polymers are soluble in the organic solvents used.

The properties of the polymers may be varied widely by the selection of the bisphenols. If different bisphenols are used together, block polymers can also be constructed in multistage polycondensations. Cycloolefinic polymers are polymers obtainable by using cyclic olefins, in particular by using polycyclic olefins.

Cyclic olefins comprise, for example, monocyclic olefins, such as cyclopentene, cyclopentadiene, cyclohexene, cycloheptene, cyclooctene, and also alkyl derivatives of these monocyclic olefins having from 1 to 3 carbon atoms, examples being methyl, ethyl or propyl, e.g. methylcyclohexene or dimethylcyclohexene, and also acrylate and/or methacrylate derivatives of these monocyclic compounds. Furthermore, cycloalkanes having olefinic side chains may also be used as cyclic olefins, an example being cyclopentyl methacrylate.

Preference is given to bridged polycyclic olefin compounds. These polycyclic olefin compounds may have the double bond either in the ring, in which case they are bridged polycyclic cycloalkenes, or else in side chains. In that case they are vinyl derivatives, allyloxycarboxy derivatives or (meth)acryloxy derivatives of polycyclic cycloalkane compounds. These compounds may also have alkyl, aryl or aralkyl substituents.

Without any intended resultant restriction, examples of polycyclic compounds are bicyclo[2.2.1]hept-2-ene (norbornene), bicyclo[2.2.1]hept-2,5-diene (2,5-norbornadiene), ethylbicyclo[2.2.1]hept-2-ene (ethylnorbornene), ethylidene-bicyclo[2.2.1]hept-2-ene (ethylidene-2-norbornene), phenylbicyclo[2.2.1]hept-2-ene, bicyclo[4.3.0]nona-3,8-diene, tricyclo[4.3.0.1^{2,5}]-3-decene, tricyclo[4.3.0.1^{2,5}]-3,8-decene-(3,8-dihydrodicyclopentadiene), tricyclo[4.4.0.1^{2,5}]-3-undecene, tetra-cyclo[4.4.0.1^{2,5},1^{7,10}]-3-dodecene, ethylidenetetracyclo[4.4.0.1^{2,5}.1^{7,10}]-3-dodecene, methyloxycarbonyltetracyclo[4.4.0.1^{2,5},1^{7,10}]-3-dodecene, ethylidene-9-ethyltetra-cyclo[4.4.01^{2,5},1^{7,10}]-3-dodecene, pentacyclo[4.7.0.1^{2,5},O,O^{3,13},1^{9,12}]-3-pentadecene, pentacyclo[6.1.1^{3,6}.0^{2,7}.0^{9,13}]-4-pentadecene, hexacyclo[6.6.1.1^{3,6}.1^{10,13}.0^{2,7}.0^{9,14}]-4-heptadecene, dimethylhexacyclo[6.6.1.1^{3,6}.1^{10,13}.0^{2,7}.0^{9,14}]-4-heptadecene, bis-(allyloxycarboxy)tricyclo[4.3.0.1^{2,5}]decane, bis(methacryloxy)tri-cyclo[4.3.0.1^{2,5}]decane, bis(acryloxy)tricyclo[4.3.0.1^{2,5}]decane.

The cycloolefinic polymers are prepared using at least one of the cycloolefinic compounds described above, in particular the polycyclic hydrocarbon compounds. The preparation of the cycloolefinic polymers may, furthermore, use other olefins which can be copolymerized with the abovementioned cycloolefinic monomers. Examples of these are ethylene, propylene, isoprene, butadiene, methylpentene, styrene, and vinyltoluene.

Most of the abovementioned olefins, and in particular the cycloolefins and polycycloolefins, may be obtained commercially. Many cyclic and polycyclic olefins are moreover obtainable by Diels-Alder addition reactions.

The cycloolefinic polymers may be prepared in a known manner, as set out inter alia in the Japanese Patent Specifications 11818/1972, 43412/1983, 1442/1986 and 19761/1987 and in the published Japanese Patent Applications Nos. 75700/1975, 129434/1980, 127728/1983, 168708/1985, 271308/1986, 221118/1988 and 180976/1990 and in the European Patent Applications EP-A-0 6 610 851, EP-A-0 6 485 893, EP-A-0 6 407 870 and EP-A-0 6 688 801.

The cycloolefinic polymers may, for example, be polymerized in a solvent, using aluminium compounds, vanadium compounds, tungsten compounds or boron compounds as catalyst.

It is assumed that, depending on the conditions, in particular on the catalyst used, the polymerization can proceed with ring-opening or with opening of the double bond. It is also possible to obtain cycloolefinic polymers by free-radical polymerization, using light or an initiator as free-radical generator. This applies in particular to the acryloyl derivatives of the cycloolefins and/or cycloalkanes. This type of polymerization may take place either in solution or else in bulk.

The use of plastic, preferably of PMMA, as outer panel with the type of layer thickness also used in conventional glass modules achieves a weight saving of the order of magnitude of 50%.

Another preferred plastic comprises poly(meth)acrylates. These polymers are generally obtained by free-radical polymerization of mixtures which comprise (meth)acrylates. The term (meth)acrylates comprises methacrylates and acrylates, and also mixtures of the two.

These monomers are well known. Among them are, inter alia, (meth)acrylates derived from saturated alcohols, e.g. methyl (meth)acrylate, ethyl (meth)acrylate, propyl (meth)acrylate, n-butyl (meth)acrylate, tert-butyl (meth)acrylate, pentyl (meth)acrylate and 2-ethylhexyl (meth)acrylate; (meth)acrylates derived from unsaturated alcohols, e.g. oleyl (meth)acrylate, 2-propynyl (meth)acrylate, allyl (meth)acrylate, vinyl (meth)acrylate; aryl (meth)acrylates, such as benzyl (meth)acrylate or phenyl (meth)acrylate, where each of the aryl radicals may be unsubstituted or have up to four substituents; cycloalkyl (meth)acrylates, such as 3-vinylcyclohexyl (meth)acrylate, bornyl (meth)acrylate; hydroxyalkyl (meth)acrylates, such as 3-hydroxypropyl (meth)acrylate, 3,4-dihydroxybutyl (meth)acrylate, 2-hydroxyethyl (meth)acrylate, 2-hydroxypropyl (meth)acrylate; glycol di(meth)acrylates, such as 1,4-butanediol di(meth)acrylate, (meth)acrylates of ether alcohols, such as tetrahydrofurfuryl (meth)acrylate, vinyloxyethoxyethyl (meth)acrylate; amides and nitriles of (meth)acrylic acid, such as N-(3-dimethylaminopropyl)(meth)acrylamide, N-(diethylphosphono)(meth)acrylamide, 1-methacryloylamido-2-methyl-2-propanol; sulfur-containing methacrylates, such as ethylsulfinylethyl (meth)acrylate, 4-thiocyanatobutyl (meth)acrylate, ethylsulfonylethyl (meth)acrylate, thiocyanatomethyl (meth)acrylate, methylsulfinylmethyl (meth)acrylate, bis((meth)acryloyloxyethyl)sulfide; multifunctional (meth)acrylates, such as trimethyloylpropane tri(meth)acrylate, pentaerythritol tetra(meth)acrylate and pentaerythritol tri(meth)acrylate.

In one preferred aspect of the present invention, these mixtures comprise at least 40% by weight, preferably at least 60% by weight, and particularly preferably at least 80% by weight, of methyl methacrylate, based on the weight of monomers.

Besides the (meth)acrylates set out above, the compositions to be polymerized may also comprise other unsaturated monomers which are copolymerizable with methyl methacrylate and with the abovementioned (meth)acrylates.

Examples of these are 1-alkenes, such as 1-hexene, 1-heptene; branched alkenes, such as vinylcyclohexane, 3,3-dimethyl-1-propene, 3-methyl-1-diisobutylene, 4-methyl-1-pentene; acrylonitrile; vinyl esters, such as vinyl acetate; styrene, substituted styrenes having one alkyl substituent in the side chain, e.g. α-methylstyrene and α-ethylstyrene, substituted styrenes having one alkyl substituent on the ring, e.g. vinyltoluene and p-methylstyrene, halogenated styrenes, such as monochlorostyrenes, dichlorostyrenes, tribromostyrenes, and tetrabromostyrenes; heterocyclic vinyl compounds, such as 2-vinylpyridine, 3-vinylpyridine, 2-methyl-5-vinylpyridine, 3-ethyl-4-vinylpyridine, 2,3-dimethyl-5-vinylpyridine, vinylpyrimidine, vinylpiperidine, 9-vinylcarbazole, 3-vinylcarbazole, 4-vinylcarbazole, 1-vinylimidazole, 2-methyl-1-vinylimidazole, N-vinylpyrrolidone, 2-vinylpyrrolidone, N-vinylpyrrolidine, 3-vinylpyrrolidine, N-vinylcaprolactam, N-vinylbutyrolactam, vinyloxolane, vinylfuran, vinylthiophene, vinylthiolane, vinylthiazoles, and hydrogenated vinylthiazoles, vinyloxazoles and hydrogenated vinyloxazoles; vinyl and isoprenyl ethers; maleic acid derivatives, such as maleic anhydride, methylmaleic anhydride, maleimide, methylmaleimide; and dienes, such as divinylbenzene.

The amount generally used of these comonomers is from 0 to 60% by weight, preferably from 0 to 40% by weight, and particularly preferably from 0 to 20% by weight, based on the weight of the monomers, and the compounds here may be used individually or as a mixture.

The polymerization reaction is generally initiated by known free-radical initiators. Examples of preferred initiators are the azo initiators well known to persons skilled in the art, e.g. AIBN and 1,1-azobiscyclohexanecarbonitrile, and also peroxy compounds, such as methyl ethyl ketone peroxide, acetylacetone peroxide, dilauryl peroxide, tert-butyl per-2-ethylhexanoate, ketone peroxide, methyl isobutyl ketone peroxide, cyclohexanone peroxide, dibenzoyl peroxide, tert-butyl peroxybenzoate, tert-butylperoxy isopropyl carbonate, 2,5-bis(2-ethylhexanoylperoxy)-2,5-dimethyl-hexane, tert-butylperoxy 2-ethylhexanoate, tert-butylperoxy 3,5,5-trimethylhexanoate, dicumyl peroxide, 1,1-bis(tert-butylperoxy)cyclohexane, 1,1-bis(tert-butylperoxy)-3,3,5-trimethylcyclohexane, cumyl hydroperoxide, tert-butyl hydroperoxide, bis(4-tert-butylcyclohexyl) peroxydicarbonate, mixtures of two or more of the above-mentioned compounds with one another, and also mixtures of the abovementioned compounds with compounds not mentioned which can likewise form free radicals.

The amount often used of these compounds is from 0.01 to 10% by weight, preferably from 0.5 to 3% by weight, based on the weight of the monomers.

The abovementioned polymers may be used individually or as a mixture. Use may also be made here of various polycarbonates, poly(meth)acrylates or cycloolefinic polymers which differ, for example, in molecular weight or in monomer composition.

The plastics substrates of the invention may, for example, be produced from moulding compositions of the abovementioned polymers. For this, use is generally made of thermoplastic shaping processes, such as extrusion or injection moulding.

The weight-average molar mass M_{w} of the homo- and/or copolymers to be used according to the invention as moulding compositions for producing the plastics substrates may vary within a wide range, the molar mass usually being matched to the application and the method used for processing the moulding composition. However, with no intended resultant restriction, it is generally in the range from 20 000 to 1 000 000 g/mol, preferably from 50 000 to 500 000 g/mol, and particularly preferably from 80 000 to 300 000 g/mol.

The plastics substrates may also be produced by cell-casting processes. In these, by way of example, suitable (meth)acrylic mixtures are charged to a mould and polymerized. These (meth)acrylic mixtures generally comprise the (meth)acrylates set out above, in particular methyl methacrylate.

The weight-average molar mass M_{w} of the polymers produced by cell-casting processes is generally higher than the molar mass of polymers used in moulding compositions. This gives rise to a number of known advantages. The weight-average molar mass of polymers which are produced by cell-casting processes is generally in the range from 500 000 to 10 000 000 g/mol, with no intended resultant restriction.

The (meth)acrylic mixtures can moreover comprise the copolymers described above and also, in particular in order to adjust viscosity, polymers, in particular poly(meth)acrylates.

Conventional additives of any type can moreover be present in the moulding compositions to be used to produce the plastics substrates, and also in the acrylic resins. Among these additives are inter alia antistatic agents, antioxidants, mould-release agents, flame retardants, lubricants, dyes, flow improvers, fillers, light stabilizers and organophosphorus compounds, such as phosphites, phosphorinanes, phospholanes or phosphonates, pigments, weathering stabilizers and plasticizers. However, the amount of additives is restricted in relation to the application.

The plastics substrates made of PMMA can optionally have been rendered impact-resistant.

Impact-modified poly(meth)acrylate

The impact-modified poly(meth)acrylate is composed of from 20% by weight to 80% by weight, preferably from 30% by weight to 70% by weight, of a poly(meth)acrylate matrix and of from 80% by weight to 20% by weight, preferably from 70% by weight to 30% by weight, of elastomer particles whose average particle diameter is from 10 to 150 nm (measurements by way of example using the ultracentrifuge method).

The elastomer particles dispersed in the poly(meth)acrylate matrix preferably have a core having a soft elastomer phase and having a hard phase bonded thereto.

The impact-modified poly(meth)acrylate plastic (imPMMA) is composed of a proportion of matrix polymer, polymerized from at least 80% by weight of units of methyl methacrylate, and also, if appropriate, from 0% by weight to 20% by weight of units of monomers copolymerizable with methyl methacrylate, and of a proportion of impact modifiers based on crosslinked poly(meth)acrylates and dispersed in the matrix.

The matrix polymer is composed in particular of from 80% by weight to 100% by weight, preferably from 90% by weight to 99.5% by weight, of methyl methacrylate units capable of free-radical polymerization and, if appropriate, from 0% by weight to 20% by weight, preferably from 0.5% by weight to 10% by weight, of further comonomers capable of free-radical polymerization, e.g. C₁-C₄-alkyl(meth)acrylates, in particular methyl acrylate, ethyl acrylate or butyl acrylate. The average (weight-average) molar mass M_{w} of the matrix is preferably in the range from 90 000 g/mol to 200 000 g/mol, in particular 100 000 g/mol to 150 000 g/mol (M, being determined by means of gel permeation chromatography with reference to polymethyl methacrylate as calibration standard). The molar mass M_{w} can be determined by gel permeation chromatography or by a light-scattering method (see, for example, H. F. Mark et al., Encyclopedia of Polymer Science and Engineering, 2nd Edition, Vol. 10, pages 1 et seq., J. Wiley, 1989).

Preference is given to a copolymer composed of from 90 to 99.5% by weight of methyl methacrylate and from 0.5 to 10% by weight of methyl acrylate. The Vicat softening points VSP (ISO 306-B50) can be in the region of at least 85° C., preferably from 95° C. to 115° C.

### The Impact Modifier

The polymethacrylate matrix comprises an impact modifier which by way of example can be an impact modifier having a two- or three-shell structure.

Impact modifiers for polymethacrylate plastics are well known. EP-A 0 113 924, EP-A 0 522 351, EP-A 0 465 049 and EP-A 0 683 028 describe by way of example the preparation and structure of impact-modified polymethacrylate moulding compositions.

### Impact Modifier

From 1% by weight to 35% by weight, preferably from 2% by weight to 20% by weight, particularly preferably from 3% by weight to 15% by weight, in particular from 5% by weight to 12% by weight, of an impact modifier which is an elastomer phase composed of crosslinked polymer particles is present in the polymethacrylate matrix. The impact modifier is obtained in a manner known per se by bead polymerization or by emulsion polymerization.

In the simplest case materials involved are crosslinked particles obtained by means of bead polymerization whose average particle size is in the range from 10 nm to 150 nm, preferably from 20 nm to 100 nm, in particular from 30 nm to 90 nm. These are generally composed of at least 40% by weight, preferably from 50% by weight to 70% by weight, of methyl methacrylate, from 20% by weight to 40% by weight, preferably from 25% by weight to 35% by weight, of butyl acrylate, and from 0.1% by weight to 2% by weight, preferably from 0.5% by weight to 1% by weight, of a crosslinking monomer, e.g. a polyfunctional (meth)acrylate, e.g. allyl methacrylate and, if appropriate, other monomers, e.g. from 0% by weight to 10% by weight, preferably from 0.5% by weight to 5% by weight, of C₁-C₄-alkyl methacrylates, such as ethyl acrylate or butyl methacrylate, preferably methyl acrylate, or other vinylically polymerizable monomers, e.g. styrene.

Preferred impact modifiers are polymer particles which can have a two- or three-layer core-shell structure and are obtained by emulsion polymerization (see, for example, EP-A 0 113 924, EP-A 0 522 351, EP-A 0 465 049 and EP-A 0 683 028). However, the invention requires suitable particle sizes of these emulsion polymers in the range from 10 nm to 150 nm, preferably from 20 nm to 120 nm, particularly preferably from 50 nm to 100 nm.

A three-layer or three-phase structure with a core and two shells can be created as follows. The innermost (hard) shell can, for example, be composed in essence of methyl methacrylate, of small proportions of comonomers, e.g. ethyl acrylate, and of a proportion of crosslinking agent, e.g. allyl methacrylate. The middle (soft) shell can, for example, be composed of butyl acrylate and, if appropriate, styrene, while the outermost (hard) shell is in essence the same as the matrix polymer, thus bringing about compatibility and good linkage to the matrix. The proportion of polybutyl acrylate in the impact modifier is decisive for the impact-modifying action and is preferably in the range from 20% by weight to 40% by weight, particularly preferably in the range from 25% by weight to 35% by weight.

### Impact-Modified Polymethacrylate Moulding Compositions

The impact modifier and matrix polymer can be mixed in the extruder in the melt to give impact-modified polymethacrylate moulding compositions. The material discharged is generally first chopped to give pellets. These can be further processed by means of extrusion or injection moulding to give mouldings, such as sheets or injection-moulded parts.

### Two-Phase Impact Modifier According to EP 0 528 196 A1

Preference is given, in particular for foil production, but not restricted thereto, to use of a system known in principle from EP 0 528 196 A1 which is a two-phase impact-modified polymer composed of:
a1) from 10% by weight to 95% by weight of a coherent hard phase whose glass transition temperature T_{mg} is above 70° C., composed of
   a11) from 80% by weight to 100% by weight (based on a1) of methyl methacrylate and
   a12) from 0% by weight to 20% by weight of one or more other ethylenically unsaturated monomers capable of free-radical polymerization, and
a2) from 90% by weight to 5% by weight of a tough phase whose glass transition temperature T_{mg} is below −10° C., distributed in the hard phase and composed of
   a21) from 50% by weight to 99.5% by weight of a C₁-C₁₀-alkyl acrylate (based on a2)
   a22) from 0.5% by weight to 5% by weight of a crosslinking monomer having two or more ethylenically unsaturated radicals which are capable of free-radical polymerization, and
   a23) if appropriate other ethylenically unsaturated monomers capable of free-radical polymerization,
      where at least 15% by weight of the hard phase a1) has covalent linkage to the tough phase a2).

The two-phase impact modifier can be produced by a two-stage emulsion polymerization reaction in water, as described by way of example in DE-A 38 42 796. In the first stage, the tough phase a2) is produced and is composed of at least 50% by weight, preferably more than 80% by weight, of lower alkyl acrylates, thus giving a glass transition temperature T_{mg} below −10° C. for this phase. Crosslinking monomers a22) used comprise (meth)acrylates of diols, e.g. ethylene glycol dimethacrylate or 1,4-butanediol dimethacrylate, aromatic compounds having two vinyl or allyl groups, e.g. divinylbenzene, or other crosslinking agents having two ethylenically unsaturated radicals which are capable of free-radical polymerization, e.g. allyl methacrylate, as graft-crosslinking agent. Crosslinking agents that may be mentioned by way of example and have three or more unsaturated groups which are capable of free-radical polymerization, e.g. allyl groups or (meth)acrylic groups, are triallyl cyanurate, trimethylolpropane triacrylate and trimethylolpropane trimethacrylate, and pentaerythrityl tetraacrylate and pentaerythrityl tetramethacrylate. U.S. Pat. No. 4,513,118 gives other examples in this connection.

The ethylenically unsaturated monomers capable of free-radical polymerization and mentioned under a23) can, by way of example, be acrylic or methacrylic acid or else their alkyl esters having from 1 to 20 carbon atoms but not mentioned above, and the alkyl radical here can be linear, branched or cyclic. Furthermore, a23) can comprise further aliphatic comonomers which are capable of free-radical polymerization and which are copolymerizable with the alkyl acrylates a21). However, the intention is to exclude significant proportions of aromatic comonomers, such as styrene, alpha-methylstyrene or vinyltoluene, since they lead to undesired properties of the moulding composition A—especially on weathering.

When the tough phase is produced in the first stage, careful attention has to be paid to the setting of the particle size and its polydispersity. The particle size of the tough phase here is in essence dependent on the concentration of the emulsifier. The particle size can advantageously be controlled by the use of a seed latex. Particles whose average (weight-average) particle size is below 130 nm, preferably below 70 nm, and whose particle-size polydispersity P₈₀ is below 0.5 (P₈₀ being determined from cumulative evaluation of the particle-size distribution determined by ultracentrifuge; the relationship is: P₈₀=[(r₉₀-r₁₀]/r₅₀]−1, where r₁₀, r₅₀, r₉₀=average cumulative particle radius, being the value which is greater than 10, 50, 90% of the particle radii and is smaller than 90, 50, 10% of the particle radii), preferably below 0.2, are achieved using emulsifier concentrations of from 0.15% by weight to 1.0% by weight, based on the aqueous phase. This applies especially to anionic emulsifiers, examples being the particularly preferred alkoxylated and sulphated paraffins. Examples of polymerization initiators used are from 0.01% by weight to 0.5% by weight of alkali metal peroxodisulphate or ammonium peroxodisulphate, based on the aqueous phase, and the polymerization reaction is initiated at temperatures of from 20 to 100° C. Preference is given to use of redox systems, an example being a combination composed of from 0.01 to 0.05% by weight of organic hydroperoxide and from 0.05 to 0.15% by weight of sodium hydroxymethylsulphinate, at temperatures of from 20 to 80° C.

The glass transition temperature of the hard phase a1) of which at least 15% by weight has covalent bonding to the tough phase a2) is at least 70° C. and this phase can be composed exclusively of methyl methacrylate. Up to 20% by weight of one or more other ethylenically unsaturated monomers which are capable of free-radical polymerization can be present as comonomers a12) in the hard phase, and the amount of alkyl (meth)acrylates used here, preferably alkyl acrylates having from 1 to 4 carbon atoms, is such that the glass transition temperature is not below the glass transition temperature mentioned above.

The polymerization of the hard phase a1) proceeds likewise in emulsion in a second stage, using the conventional auxiliaries, for example those also used for polymerization of the tough phase a2).

In one preferred embodiment, the hard phase comprises amounts of from 0.1 to 10% by weight, preferably from 0.5 to 5% by weight, of low-molecular-weight and/or copolymerized UV absorbers, based on A as constituent of the comonomeric components a12) in the hard phase. An example that may be mentioned of the polymerizable UV absorbers, as described inter alia in U.S. Pat. No. 4,576,870, is 2-(2′-hydroxyphenyl)-5-methacrylamidobenzotriazole or 2-hydroxy-4-methacryloxy-benzophenone. By way of example, low-molecular-weight UV absorbers can be derivatives of 2-hydroxybenzophenone or of 2-hydroxyphenylbenzotriazole, or can be phenyl salicylates. The molar mass of the low-molecular-weight UV absorbers is generally less than 2×10³ (g/mol). Particular preference is given to UV absorbers with low volatility at the processing temperature which can be mixed homogeneously with the hard phase a1) of the polymer A.

Particularly preferred moulding compositions which comprise poly(meth)acrylates are commercially obtainable with trademark PLEXIGLAS®from Evonik Röhm.

Preferred moulding compositions which comprise cycloolefinic polymers can be purchased with trademark Topas® from Ticona and Zeonex® from Nippon Zeon. Polycarbonate moulding compositions are obtainable by way of example with trademark Makrolon® from Bayer or Lexan® from General Electric.

The plastic particularly preferably comprises at least 80% by weight, in particular at least 90% by weight, based on the total weight of the substrate, of poly(meth)acrylates, polycarbonates and/or cycloolefinic polymers.

The plastics substrates are particularly preferably composed of polymethyl methacrylate, where the polymethyl methacrylate can comprise conventional additives.

According to one preferred embodiment, plastics can have impact resistance to ISO 179/1 of at least 10 kJ/m², preferably at least 15 kJ/m².

According to another embodiment, the plastic can have a scratch-resistant coating.

Scratch-resistant siloxane lacquers which can be used to produce the coating are known per se, and are used on polymeric glazing materials. Their inorganic character gives them good resistance to UV radiation and to weathering. By way of example, the production of these lacquers is described in EP-A-0 073911. Conventional lacquers are, inter alia, those which comprise water and/or alcohol as solvent, besides the siloxane condensation products.

These siloxane lacquers may be obtained, inter alia, by condensation or hydrolysis of organosilicon compounds of the general formula (I)

R¹ₙSiX₄₋n (I),

where R¹ is a group having from 1 to 20 carbon atoms, X is an alkoxy radical having from 1 to 20 carbon atoms, or a halogen, and n is an integer from 0 to 3, and where the various radicals X or R¹ may in each case be identical or different.

The expression “a group having from 1 to 20 carbon atoms” characterizes radicals of organic compounds having from 1 to 20 carbon atoms. It comprises alkyl groups, cycloalkyl groups, aromatic groups, alkenyl groups and alkynyl groups having from 1 to 20 carbon atoms, and also heteroaliphatic and heteroaromatic groups which have in particular oxygen atoms, nitrogen atoms, sulphur atoms and phosphorus atoms, besides carbon atoms and hydrogen atoms. These groups mentioned may be branched or unbranched, and the radical R¹ here may be substituted or unsubstituted. Among the substituents are in particular halogens, groups having from 1 to 20 carbon atoms, nitro groups, sulphonic acid groups, alkoxy groups, cycloalkoxy groups, alkanoyl groups, alkoxycarbonyl groups, sulphonic ester groups, sulphinic acid groups, sulphinic ester groups, thiol groups, cyanide groups, epoxy groups, (meth)acryloyl groups, amino groups and hydroxy groups. For the purposes of the present invention, the term “halogen” means a fluorine atom, chlorine atom, bromine atom or iodine atom.

Among the preferred alkyl groups are the methyl, ethyl, propyl, isopropyl, 1-butyl, 2-butyl, 2-methylpropyl, tert-butyl, pentyl, 2-methylbutyl, 1,1-dimethylpropyl, hexyl, heptyl, octyl, 1,1,3,3-tetramethylbutyl, nonyl, 1-decyl, 2-decyl, undecyl, dodecyl, pentadecyl group, and the eicosyl group.

Examples of preferred cycloalkyl groups are the cyclopropyl, cyclobutyl, cyclopentyl, cyclohexyl and cycloheptyl group, and the cyclooctyl group, these having substitution, where appropriate, by branched or unbranched alkyl groups.

Among the preferred alkenyl groups are the vinyl, allyl, 2-methyl-2-propene, 2-butenyl, 2-pentenyl, 2-decenyl group, and the 2-eicosenyl group.

Among the preferred alkynyl groups are the ethynyl, propargyl, 2-methyl-2-propyne, 2-butynyl, 2-pentynyl group, and the 2-decynyl group.

Among the preferred alkanoyl groups are the formyl, acetyl, propionyl, 2-methylpropionyl, butyryl, valeroyl, pivaloyl, hexanoyl, decanoyl group, and the dodecanoyl group.

Among the preferred alkoxycarbonyl groups are the methoxycarbonyl, ethoxycarbonyl, propoxycarbonyl, butoxycarbonyl, tert-butoxycarbonyl, hexyloxycarbonyl, 2-methylhexyloxycarbonyl, or decyloxycarbonyl group, or dodecyloxycarbonyl group.

Among the preferred alkoxy groups are the methoxy, ethoxy, propoxy, butoxy, tert-butoxy, hexyloxy, 2-methylhexyloxy, or decyloxy group, or dodecyloxy group.

Examples of preferred cycloalkoxy groups are cycloalkoxy groups whose hydrocarbon radical is one of the abovementioned preferred cycloalkyl groups.

Among the preferred heteroaliphatic groups are the abovementioned preferred cycloalkyl radicals in which at least one carbon unit has been replaced by O, S or an NR⁸ group, R⁸ being hydrogen or an alkyl group having from 1 to 6 carbon atoms, or being an alkoxy or aryl group having from 1 to 6 carbon atoms.

According to the invention, aromatic groups are radicals of one or polynuclear aromatic compounds preferably having from 6 to 14 carbon atoms, in particular from 6 to 12 carbon atoms. Heteroaromatic groups are aryl radicals in which at least one CH group has been replaced by N, and/or at least two adjacent CH groups have been replaced by S, NH or O. According to the invention, preferred aromatic or heteroaromatic groups derive from benzene, naphthalene, biphenyl, diphenyl ether, diphenylmethane, diphenyldimethylmethane, bisphenone, diphenyl sulphone, thiophene, furan, pyrrole, thiazole, oxazole, imidazole, isothiazole, isoxazole, pyrazole, 1,3,4-oxadiazole, 2,5-diphenyl-1,3,4-oxadiazole, 1,3,4-thiadiazole, 1,3,4-triazole, 2,5-diphenyl-1,3,4-triazole, 1,2,5-triphenyl-1,3,4-triazole, 1,2,4-oxadiazole, 1,2,4-thiadiazole, 1,2,4-triazole, 1,2,3-triazole, 1,2,3,4-tetrazole, benzo[b]thiophene, benzo[b]furan, indole, benzo[c]thiophene, benzo[c]furan, isoindole, benzoxazole, benzothiazole, benzimidazole, benzisoxazole, benzisothiazole, benzopyrazole, benzothiadiazole, benzotriazole, dibenzofuran, dibenzothiophene, carbazole, pyridine, pyrazine, pyrimidine, pyridazine, 1,3,5-triazine, 1,2,4-triazine, 1,2,4,5-triazine, quinoline, isoquinoline, quinoxaline, quinazoline, cinnoline, 1,8-naphthyridine, 1,5-naphthyridine, 1,6-naphthyridine, 1,7-naphthyridine, phthalazine, pyridopyrimidine, purine, pteridine, or 4H-quinolizine, diphenyl ether, anthracene and phenanthrene.

Preferred radicals R¹ can be represented by the formulae (II),

—(CH₂)ₘNH—[(CH₂)ₙ—NH]ₚH (II),

where m and n are numbers from 1 to 6, and p is zero or one, or the formula (III)

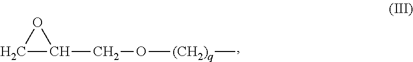

where q is a number from 1 to 6,
or the formula (IV)

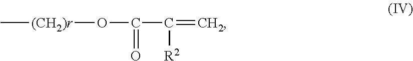

where R² is methyl or hydrogen and r is a number from 1 to 6.

The radical R¹ is very particularly preferably a methyl or ethyl group.

In relation to the definition of the group X in formula (I) in respect of the alkoxy group having from 1 to 20 carbon atoms and also of the halogen, reference may be made to the abovementioned definition, where the alkyl radical of the alkoxy group may likewise preferably be represented by the formulae (II), (III) or (IV) set out above. The group X preferably represents a methoxy or ethoxy radical or a bromine or chlorine atom.

These compounds may be used individually or as a mixture to prepare siloxane lacquers.

Depending on the number of the halogens or on the number of alkoxy groups bonded by oxygen to silicon, hydrolysis or condensation forms chains or branched siloxanes from the silane compounds of the formula (I). It is preferable for at least 60% by weight, in particular at least 80% by weight, of the silane compounds used to have at least three alkoxy groups or halogen atoms, based on the weight of the condensable silanes.

Tetraalkoxysilanes comprise tetramethoxysilane, tetraethoxysilane, tetra-n-propoxysilane, tetraisopropoxysilane and tetra-n-butoxysilanes;

trialkoxysilanes comprise methyltrimethoxysilane, methyltriethoxysilane, ethyltrimethoxysilane, n-propyltrimethoxysilane, n-propyltriethoxysilane, isopropyl-triethoxysilane, isopropyltrimethoxysilane, isopropyltripropoxysilane, n-butyltrimethoxysilane, n-butyltriethoxysilane, n-pentyltrimethoxysilane, n-hexyltri-methoxysilane, n-heptyltrimethoxysilane, n-octyltrimethoxysilane, vinyltrimethoxysilane, vinyltriethoxysilane, cyclohexyltrimethoxysilane, cyclohexyltri-ethoxysilane, phenyltrimethoxysilane, 3-chloropropyltrimethoxysilane, 3-chloropropyltriethoxysilane, 3,3,3-trifluoropropyltrimethoxysilane, 3,3,3-trifluoropropyl-triethoxysilane, 3-aminopropyltrimethoxysilane, 3-aminopropyltriethoxysilane, 2-hydroxyethyltrimethoxysilane, 2-hydroxyethyltriethoxysilane, 2-hydroxypropyl-trimethoxysilane, 2-hydroxypropyltriethoxysilane, 3-hydroxypropyltrimethoxysilane, 3-hydroxypropyltriethoxysilane, 3-mercaptopropyltrimethoxysilane, 3-mercaptopropyl-triethoxysilane, 3-isocyanatopropyltrimethoxysilane, 3-isocyanatopropyltriethoxysilane, 3-glycidoxypropyltrimethoxysilane, 3-glycidoxypropyltriethoxysilane, 2-(3,4-epoxycyclohexyl)ethyltrimethoxysilane, epoxycyclohexypethyltriethoxysilane, 3-(meth)acryloxypropyltrimethoxysilane, 3-(meth)acryloxypropyltriethoxysilane, 3-ureidopropyltrimethoxysilane and 3-ureidopropyltriethoxysilane;
dialkoxysilanes comprise dimethyldimethoxysilane, dimethyldiethoxysilane, diethyldimethoxysilane, diethyldiethoxysilane, di-n-propyldimethoxysilane, di-n-propyldiethoxysilane, diisopropyldimethoxysilane, diisopropyldiethoxysilane, di-n-butyldimethoxysilane, di-n-butyldiethoxysilane, di-n-pentyldimethoxysilane, di-n-pentyldiethoxysilane, di-n-hexyldimethoxysilane, di-n-hexyldiethoxysilane, di-n-peptyldimethoxysilane, di-n-peptyldiethoxysilane, di-n-octyldimethoxysilane, di-n-octyldiethoxysi lane, di-n-cyclohexyldimethoxysilane, di-n-cyclohexyldiethoxysilane, diphenyldimethoxysilane and diphenyldiethoxysilane.

Particular preference is given to methyltrimethoxysilane, methyltriethoxysilane, ethyl-trimethoxysilane and ethyltriethoxysilane. In one particular aspect of the present invention, the proportion of these particularly preferred alkyltrialkoxysilanes is at least 80% by weight, in particular at least 90% by weight, based on the weight of the silane compounds used.

The siloxane lacquers described above can be obtained commercially with trademark Acriplex® 100 and Acriplex® 180 SR from Evonik Röhm GmbH.

The plastics panel can be flat or by way of example can have been curved by a prior forming process.

The radius of curvature of the plastics panel can be from 0.4 m to 100 m, preferably from 0.5 m to 80 m and very particularly preferably from 0.6 m to 60 m.

The modulus of elasticity of the durably elastic intermediate layer must be at most 500 MPa to DIN ISO 527, and it must have good adhesion to the plastics panel, to the PV cells, and also to the barrier layer. A primer can be used as adhesion promoter if necessary to improve the adhesion. Examples of suitable substrates for the elastic intermediate layer are acrylates (DuploCOLL® VP20618 or CPT 3000 from Lohmann), silicones (Silgel® 612 from Wacker), polyurethanes (Vestanat® T/Oxyester T from Evonik) or thermoplastic elastomers (TPU Krystalflex® PE 429 from Huntsman)

Silicone resins in aliphatic hydrocarbon can be used as primer (an example being G 790 primer from Wacker).

PV cells that can be used are any of the known types of cell, examples being monocrystalline and multicrystalline silicon cells and thin-layer PV cells.

Familiar transparent or non-transparent plastics foils, optionally with an adhesion-promoting coating, can be used as barrier layer (PET, e.g. Tritan® FX 100 (Eastman), PVF e.g. Tedlar® (DuPont), PMMA e.g. FLEX® 8943 F (Evonik Röhm GmbH)).

### Production of the PV Module

The production process for the PV module uses lamination in a moderate temperature range (for example about 0 degrees C. to 90 degrees C., preferably from 10 degrees C. to 80 degrees C. and very particularly preferably from 15 degrees C. to 75 degrees C.).

The elastic intermediate layer can be applied in one or two stages in the form of foils or in the form of thermoplastic or liquid, optionally reactive components (e.g. 2-component systems).

### Variant 1:

For this, a foil (2a) of the elastic intermediate layer is applied to the plastics panel (1). The PV cells previously soldered to give strings are then superposed, and then are protectively covered with a second foil (2b) of the elastic intermediate layer. Finally, the barrier foil (3) is applied.

### Variant 2:

When the barrier foil as composite foil has been equipped monolaterally with the elastic intermediate layer (3+2b) the separate step using the foil (2b) becomes superfluous.

The resultant composite is then pressed in a suitable mould which has been adapted appropriately to the geometry or curvature of the plastics panel. This step is characterized in that it can take place without supply of heat or with only slight supply of heat.

The pressure is from 0.001 N/mm² to 10 N/mm², preferably from 0.01 N/mm² to 5 N/mm² and very particularly preferably from 0.03 N/mm² to 3 N/mm².

If necessary, the pressing process can take place in vacuo in order to remove air inclusions, and in this case the pressure ranges from 0.00001 bar to 0.9 bar, preferably within the range from 0.0001 bar to 0.5 bar, very particularly preferably within the range from 0.001 bar to 0.3 bar.

As an alternative, in one particularly cost-effective process, the elastic intermediate layer (2a) is continuously laminated by way of example in a roller laminator to the plastics panel (1).

Once the string has been superposed, the second elastic intermediate layer (2b) is applied in a further continuous lamination step and finally, in a third continuous lamination step the barrier foil (3) is applied. The second and third lamination step can advantageously coincide, if the barrier foil has been equipped in advance monolaterally with the elastic intermediate layer (3+2b).

If necessary, the lamination process can take place in vacuo in order to remove air inclusions.

### EXAMPLES

### Batchwise Production of a Module Using Acrylate Embedding Composition

A sheet of PMMA/solar PMMA (trademark: PLEXIGLAS® Solar, produced and marketed by Evonik Röhm GmbH) is coated in a laminator using an acrylate adhesive layer (DupIoCOLL® CPT 500, produced by Lohmann). For this, the PMMA sheet is conducted from below into the nip and the adhesive foil is conducted from above into the nip. The width of the nip is equal to the total of the thicknesses of the individual components minus zero to five tenths of a millimetre. Photovoltaic cells are then preferably placed in vacuo onto the sheet and the composite is again laminated using an acrylate adhesive layer. The width of the nip is calculated from the formula used for the first lamination process. A barrier foil is then laminated to the adhesive foil to seal the module. The composite can then also be provided with a metal sheet or with a sandwich component. All of the steps take place at room temperature.

### Continuous Production of a Module Using Acrylate Embedding Composition:

Directly after the extrusion process, a continuous web of PMMA/solar PMMA (trademark: PLEXIGLAS® Solar, produced and marketed by Evonik Röhm GmbH) is coated in a laminator using an acrylate adhesive layer (DupIoCOLL® CPT 500, produced by Lohmann). For this, the continuous web of PMMA is conducted into the nip from below and the adhesive foil is conducted into the nip from above. The width of the nip is equal to the total of the thicknesses of the individual components minus zero to five tenths of a millimetre.

Photovoltaic cells are then preferably placed in vacuo onto the sheet and the composite is again laminated using an acrylate adhesive layer. The width of the nip is calculated from the formula used for the first lamination process.

A barrier foil is then laminated to the adhesive foil to seal the module.

The composite can then also be provided with a metal sheet or with a sandwich component. At the end of the section, there is then a lamination process and the continuous web is cut to length to give individual modules. All of the steps take place at room temperature.

### Batchwise Production of a Module Using Silicone Embedding Composition

One or more dispenser(s) is/are used to apply one sort of silicone (Silgel® 612 from Wacker) or more than one type of silicone to a sheet of PMMA/solar PMMA (trademark: PLEXIGLAS® Solar, produced and marketed by Evonik Röhm GmbH). The application thickness is from 0.5 mm to 3 mm. The reaction of the silicone layer is then carried out under UV sources or infrared sources or a combination of the two.

Photovoltaic cells are then preferably placed in vacuo onto the sheet. A layer of silicone is again applied to the composite. The said layer can again be composed of more than one type of silicone and its thickness is from 0.5 mm to 3 mm.

The reaction of the silicone layer is then carried out under UV sources or infrared sources or a combination of the two.

A barrier foil is then laminated to the composite to seal the module.

The width of the nip is equal to the total of the thicknesses of the individual components minus zero to five tenths of a millimetre.

The composite can then also be provided with a metal sheet or with a sandwich component.

### Continuous Production of a Module Using Silicone Embedding Composition:

Directly following the extrusion process, one or more dispenser(s) is/are used to apply one type of silicone (Silgel® 612 from Wacker) or more than one type of silicone to a continuous web of PMMA/solar PMMA (trademark: PLEXIGLAS® Solar, produced and marketed by Evonik Röhm GmbH). The application thickness is from 0.5 mm to 3 mm. The silicone layer is then carried out under UV sources or infrared sources or a combination of the two.

Photovoltaic cells are then preferably placed in vacuo onto the sheet. A layer of silicone is again applied to the composite. The said layer can again be composed of more than one type of silicone and its thickness is from 0.5 mm to 3 mm.

The reaction of the silicone layer is then carried out under UV sources or infrared sources or a combination of the two.

A barrier foil is then laminated to the composite to seal the module.

The width of the nip is equal to the total of the thicknesses of the individual components minus zero to five tenths of a millimetre.

The composite can then also be provided with a metal sheet or with a sandwich component. At the end of the section there is then a lamination process and the continuous web is cut to length to give individual modules.

### Batchwise Production of a Module Using Silicone Embedding Composition:

One or more dispenser(s) is/are used to apply one type of silicone (Silgel® 612 from Wacker) or more than one type of silicone to a sheet of PMMA/solar PMMA (trademark: PLEXIGLAS® Solar, produced and marketed by Evonik Röhm GmbH). The application thickness is from 0.5 mm to 3 mm. The silicone layer is then carried out under UV sources or infrared sources or a combination of the two.

Photovoltaic cells are then preferably placed in vacuo onto the sheet. A layer of silicone is again applied to the composite. The said layer can again be composed of more than one type of silicone and its thickness is from 0.5 mm to 3 mm.

The reaction of the silicone layer is then carried out under UV sources or infrared sources or a combination of the two.

A barrier foil is then laminated to the composite to seal the module.

The width of the nip is equal to the total of the thicknesses of the individual components minus zero to five tenths of a millimetre.

The composite can then also be provided with a metal sheet or with a sandwich component.

### Continuous Production of a Module Using Polyurethane Embedding Composition:

Directly following the extrusion process, one or more dispenser(s) is/are used to apply a mixture made of one sort or of more than one sort of polyester (Oxyester T1136, produced by EVONIK) and of one or more polyfunctional isocyanates (VESTANAT® T6040, produced by EVONIK) to a continuous web of PMMA/solar PMMA (trademark: PLEXIGLAS® Solar, produced and marketed by Evonik Röhm GmbH). The application thickness is from 0.5 mm to 3 mm. The reaction of the polyurethane layer is then carried out under UV sources or infrared sources or a combination of the two.

Photovoltaic cells are then preferably placed in vacuo onto the sheet. A layer of polyurethane is again applied to the composite. The said layer can again be composed of more than one type of polyurethane and its thickness is from 0.5 mm to 3 mm.

The reaction of the polyurethane layer is then carried out under UV sources or infrared sources or a combination of the two.

A barrier foil is then laminated to the composite to seal the module.

The width of the nip is equal to the total of the thicknesses of the individual components minus zero to five tenths of a millimetre.

The composite can then also be provided with a metal sheet or with a sandwich component. At the end of the section there is then a lamination process, and the continuous web is cut to length to give individual modules.

### Batchwise Production of a Module Using TPU Embedding Composition:

A sheet of PMMA/solar PMMA (trademark: PLEXIGLAS® Solar, produced and marketed by Evonik Röhm GmbH) is coated in a laminator using a TPU layer (Krystalflex® PE 429, produced by Huntsman). For this, the PMMA sheet is conducted into the nip from below and the TPU foil is conducted, with heating, into the nip from above. The width of the nip is equal to the total of the thicknesses of the individual components minus zero to five tenths of a millimetre.

Photovoltaic cells are then preferably placed in vacuo onto the sheet and the composite is again laminated using an adhesive layer made of a TPU. The width of the nip is calculated from the formula used for the first lamination process.

A barrier foil is then laminated to the adhesive foil to seal the module.

The composite can then also be provided with a metal sheet or with a sandwich component. All of the steps take place at room temperature.

### Continuous Production of a Module Using TPU Embedding Composition:

Directly after the extrusion process, a continuous web of PMMA/solar PMMA (trademark: PLEXIGLAS® Solar, produced and marketed by Evonik Röhm GmbH) is coated in a laminator using a TPU layer (Krystalflex® PE 429, produced by Huntsman). For this, the continuous web of PMMA is conducted into the nip from below and the TPU foil is conducted into the nip from above. The width of the nip is equal to the total of the thicknesses of the individual components minus zero to five tenths of a millimetre.

Photovoltaic cells are then preferably placed in vacuo onto the sheet and the composite is again laminated using a TPU adhesive layer. The width of the nip is calculated from the formula used for the first lamination process.

A barrier foil is then laminated to the adhesive foil to seal the module. At the end of the section there is then a lamination process, and the continuous web is cut to length to give individual modules.

The composite can then also be provided with a metal sheet or with a sandwich component.

All of the steps take place at room temperature.

### Results

The PV modules were tested for weathering resistance. The PV modules according to the invention are generally highly resistant to weathering. Weathering resistance to DIN 53387 (Xenotest) is therefore at least 5000 hours.

Yellowness index to DIN 6167 (D65/10) of preferred plastics is smaller than or equal to 8 even after a long period of UV irradiation of more than 5000 hours, preferably smaller than or equal to 5, with no intended resultant restriction.

1. Photovoltaic module, composed of the following elements:
a. an outer layer made of a transparent thermoplastic and/or a barrier foil,
b. an elastic layer into which the solar cells have been embedded and
c. a barrier foil or a barrier sheet.

2. Photovoltaic module according to claim 1,
characterized in that
PMMA is used as transparent thermoplastic.

3. Photovoltaic module according to claim 1,
characterized in that
the modulus of elasticity of the elastic layer is at most 500 MPa to
DIN ISO 527.

4. Process for producing a PV module according to 1,
characterized in that
the layers are laminated at temperatures below 90 degrees C.

5. Process for producing a PV module according to 1,
characterized in that
the lamination of the layers takes place in a vacuum press.

6. Process for producing a PV module according to 1,
characterized in that
the layers are applied in a continuous lamination process.

7. Process for producing a PV module according to 1,
characterized in that
the layers are applied in a continuous lamination process in vacuo.

8. Process for producing a PV module according to 1,
characterized in that
the elastic layers are applied as foils.

9. Process for producing a PV module according to 1,
characterized in that
the elastic layers are applied in liquid form.
